(19) United States
(12) Patent Application Publication
(10) Pub. No.: US 2014/0077339 A1
(43) Pub. Date: Mar. 20, 2014

(54) DELTA DOPING AT Si-Ge INTERFACE

(71) Applicants: Radek Roucka, Mountain View, CA (US); Michael Lebby, Apache Junction, AZ (US); Scott Semans, Sunnyvale, CA (US)

(72) Inventors: Radek Roucka, Mountain View, CA (US); Michael Lebby, Apache Junction, AZ (US); Scott Semans, Sunnyvale, CA (US)

(21) Appl. No.: 13/619,883

(22) Filed: Sep. 14, 2012

(51) Int. Cl. H01L 21/02; H01L 29/12

(52) U.S. Cl. CPC H01L 21/02584; H01L 29/12
USPC 257/616; 438/478

(57) ABSTRACT

A IV or III-V device is fabricated on a germanium template on a silicon substrate and includes a thin layer of Ge epitaxially grown on a silicon substrate. The thin layer includes Ge delta doped with Sn at the silicon substrate. A single crystal layer of Ge is epitaxially grown on the thin layer of Ge doped with Sn. A structure including one of IV material and III-V material is epitaxially grown on the single crystal layer of Ge.

### FIELD OF THE INVENTION

This invention relates in general to the formation of a Ge template on a silicon wafer.

### BACKGROUND OF THE INVENTION

In the solar cell industry, it is known that germanium (Ge) is a desirable semiconductor material that absorbs substantial amounts of solar energy and is also useful in other photonic devices. Ge templates can be used for the subsequent growth of IV and III-V materials used in many photonic/electronic/solar devices. In prior art commercial solar cells for example, 3 junctions using III-V materials are deployed on a germanium substrate to emulate or match the solar spectrum. The germanium substrates are used because it is extremely difficult to grow high quality germanium on silicon substrates. There are major problems with the use of germanium wafers. Germanium wafers are expensive and constitute approximately 50% of the total cost of the device. Also, germanium wafers are heavy and very brittle so that they are generally limited in size to less than 6″ in diameter. Further, because the wafers are brittle they must be relatively thick which due to the thermal conductivity issue creates a cooling problem.

Presently, it has been found that the addition of tin (Sn) to germanium extends the absorption spectrum of a solar cell into lower energy light. However, efforts to grow sufficiently thick layers of GeSn or SiGeSn have been largely unsuccessful. In the prior art efforts to grow GeSn incorporating a constant mole fraction of SN on silicon substrates has resulted in the layers having a limited thickness because of cracking and stress fractures. As an example, a description of one such prior art method can be found in U.S. Pat. No. 7,589,003, entitled “GESN Alloys and Ordered Phases with Direct Tunable Bandgaps Grown Directly on Silicon”, issued Sep. 15, 2009.

It would be highly advantageous, therefore, to remedy the foregoing and other deficiencies inherent in the prior art.

Accordingly, it is an object of the present invention to provide new and improved methods for the growth of single crystal germanium templates on single crystal silicon substrates.

It is another object of the present invention to provide new and improved methods of growing IV and III-V materials on silicon substrates.

It is another object of the present invention to provide new and improved devices including IV and III-V materials on silicon substrates.

### SUMMARY OF THE INVENTION

Briefly, the desired objects and aspects of the instant invention are achieved in accordance with a preferred method of fabricating a germanium template on a silicon substrate including the steps of providing a crystalline silicon substrate and epitaxially growing a thin layer of Ge doped with Sn on the silicon substrate. The Sn is distributed adjacent the silicon substrate. A single crystal layer of Ge is epitaxially grown on the thin layer of Ge doped with Sn to provide a template for further epitaxial growth.

The desired objects and aspects of the instant invention are also realized in accordance with a specific method of fabricating a germanium template on a silicon substrate including the steps of providing a crystalline silicon substrate, epitaxially growing a thin layer of Ge including delta doping the Ge with Sn at the silicon substrate, and epitaxially growing a single crystal layer of Ge on the thin layer of Ge doped with Sn to provide a template for further epitaxial growth. A structure including one of IV material and III-V material is epitaxially grown on the single crystal layer of Ge.

The desired objects and aspects of the instant invention are also realized in accordance with a specific embodiment of a device including a germanium template grown on a silicon substrate including a crystalline silicon substrate, and a thin layer of Ge doped with Sn epitaxially grown on the silicon substrate, the Sn being distributed adjacent the silicon substrate. A single crystal layer of Ge is epitaxially grown on the thin layer of Ge doped with Sn to provide a template for further epitaxial growth.

The desired objects and aspects of the instant invention are further realized in accordance with a specific embodiment of a IV or III-V device fabricated on a germanium template on a silicon substrate. The device includes a crystalline silicon substrate with a thin layer of Ge epitaxially grown on the silicon substrate, the thin layer including Ge delta doped with Sn at the silicon substrate. A single crystal layer of Ge is epitaxially grown on the thin layer of Ge doped with Sn. A structure including one of IV material and III-V material is epitaxially grown on the single crystal layer of Ge.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram of a Ge template on a silicon substrate in accordance with the present invention; and

FIG. 2 is a simplified layer diagram of IV/III-V solar material grown on the Ge template of FIG. 1, in accordance with the present invention.

### DETAILED DESCRIPTION OF THE DRAWINGS

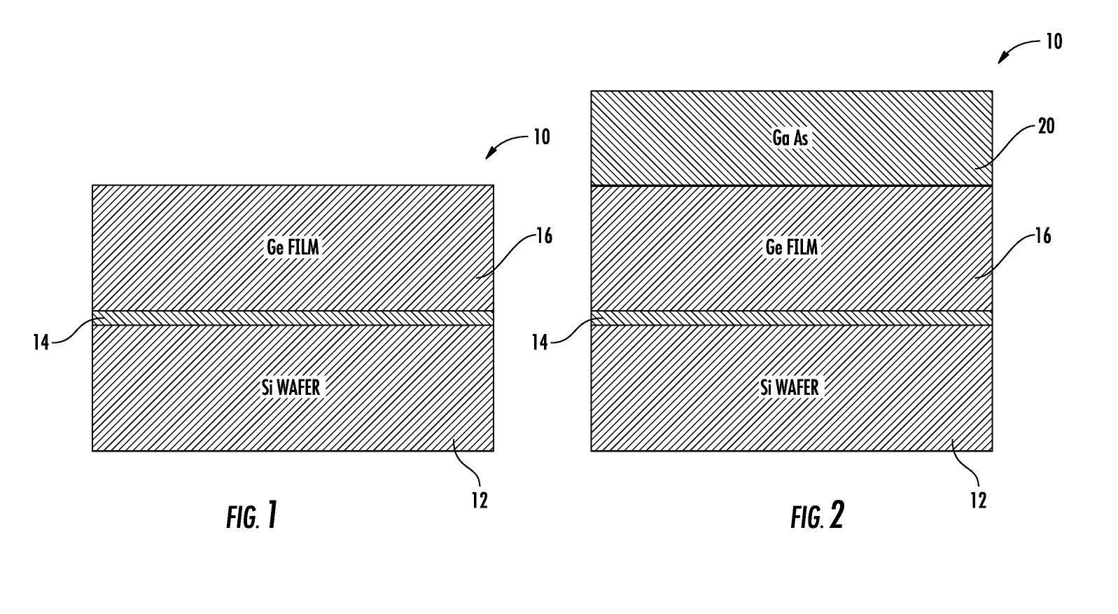

Turning to FIG. 1, a simplified layer diagram is illustrated of a Ge template 10 on a silicon substrate 12. Substrate 12 includes single crystal silicon which, it will be understood, is or may be a standard well know single crystal silicon wafer or portion thereof generally known and used in the semiconductor industry. Single crystal silicon substrate 12, it will be understood, is not limited to any specific crystal orientation but could include <111> silicon, <110> silicon, <100> silicon or any other orientation or variation known and used in the art, such as miscuts with nominal value between 0 and 10° in any direction.

As is understood in the art, there is a substantial crystal lattice mismatch between silicon and germanium (4%). Because of this lattice mismatch flat, single crystal germanium cannot be grown on silicon substrates/wafers. The strain due to the mismatch results in cracks, fractures and other crystalline flaws which grow worse as the growth of thicker layers (e.g. >3 μm) is attempted. Further, the growth of additional IV and/or III-V materials on template 10 requires that template 10 has good crystalline quality.

To solve this problem a thin layer 14 of Ge with Sn distributed therethrough is formed on the surface of silicon substrate 12 initially during the formation of template 10. Layer 14 is approximately 5 nm thick or less and includes Ge with a high concentration of Sn (i.e. 0.5% to 100%). The Sn is used as a dopant at the Si—Ge interface in a very thin region (layer 14). Preferably, the Sn is introduced into the Ge in a process known as delta (δ) doping or delta doped. As understood by the artisan, the technique of δ doping is applicable to epitaxially deposited semiconductor materials and involves interruption of the growth of the matrix material (Ge) to allow the dopant to be deposited. Matrix growth is then started again with the dopant being confined to the plane on which it was deposited. In the present structure the result is a delta-function-like spike of Sn at the growth interruption area, i.e. layer 14, adjacent silicon substrate 12.

The Sn in thin layer 14 at the Si—Ge interface softens the material and allows the mismatch strain between Si and Ge to be relaxed. The epitaxial growth of Ge continues on layer 14 resulting in a thick layer 16 (approximately 3 μm to approximately 5 μm) of pure Ge. The properties of the Ge in layer 16 are not affected by the incorporation of Sn in thin layer 14 and layer 16 has a flat, high quality crystalline surface. While layers 14 and 16 are referred to herein as separate layers for convenience in understanding, it should be understood that essentially a single layer of germanium is epitaxially grown and the single layer is delta doped at the surface of silicon substrate 12 with tin (Sn) to reduce the stress between the silicon and the germanium.

Referring additionally to FIG. 2, a structure 20 of IV and/or III-V material is epitaxially grown on the surface of Ge layer 16 (template 10). While structure 20 is illustrated as a single layer for convenience, it will be understood that it may include from one to several layers of IV and/or III-V material and each layer may be different and the layers may have different thicknesses to accomplish different purposes. Generally, the IV material may include SiGeSn, GeSn, Ge or any combinations including any of these materials and the III-V material may include GaAs, InGaAS, InGaP, or any combinations including any of these materials. For example, applications of GaAs include photonics, electronics, or solar collectors.

Thus, new and improved methods for the growth of single crystal germanium templates on single crystal silicon substrates are disclosed. Also, new and improved methods of growing IV and III-V materials on silicon substrates are disclosed. Primarily, tin (Sn) is used in a template only at the Si—Ge interface and in a very thin layer. A 5 um layer of germanium can then be grown on the layer containing tin and will have a flat high quality crystalline surface. New and improved devices including IV and III-V materials can then be grown on the Ge template.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of fabricating a germanium template on a silicon substrate comprising the steps of:
providing a crystalline silicon substrate;
epitaxially growing a thin layer of Ge doped with Sn on the silicon substrate, the Sn being distributed adjacent the silicon substrate; and
epitaxially growing a single crystal layer of Ge on the thin layer of Ge doped with Sn.

2. A method as claimed in claim 1 wherein the step of epitaxially growing the thin layer of Ge doped with Sn includes doping the Ge with a spike of Sn adjacent the silicon substrate.

3. A method as claimed in claim 1 wherein the step of epitaxially growing the thin layer of Ge doped with Sn includes delta (δ) doping the Ge with Sn adjacent the silicon substrate.

4. A method as claimed in claim 1 wherein the step of epitaxially growing the thin layer of Ge doped with Sn includes growing a layer 5 nm thick or less.

5. A method as claimed in claim 1 wherein the step of epitaxially growing a thin layer of Ge doped with Sn includes growing a layer with a concentration of Sn in a range of 0.5% to 100%.

6. A method as claimed in claim 1 further including a step of epitaxially growing a structure including one of IV material and III-V material on the single crystal layer of Ge.

7. A method as claimed in claim 1 further including a step of epitaxially growing a structure includes growing a layer of GaAs on the single crystal layer of Ge.

8. A method of fabricating a germanium template on a silicon substrate comprising the steps of:
providing a crystalline silicon substrate;
epitaxially growing a thin layer of Ge including delta doping the Ge with Sn at the silicon substrate;
epitaxially growing a single crystal layer of Ge on the thin layer of Ge doped with Sn; and
epitaxially growing a structure including one of IV material and III-V material on the single crystal layer of Ge.

9. A method as claimed in claim 8 wherein the step of epitaxially growing the structure includes growing at least a layer including GaAs.

10. A device including a germanium template grown on a silicon substrate comprising:
a crystalline silicon substrate;
a thin layer of Ge doped with Sn epitaxially grown on the silicon substrate, the Sn being distributed adjacent the silicon substrate; and
a single crystal layer of Ge epitaxially grown on the thin layer of Ge doped with Sn.

11. A device as claimed in claim 10 wherein the epitaxially grown thin layer of Ge doped with Sn includes the Ge being doped with a spike of Sn adjacent the silicon substrate.

12. A device as claimed in claim 10 wherein the epitaxially grown thin layer of Ge doped with Sn includes the Ge being delta (δ) doped with Sn adjacent the silicon substrate.

13. A device as claimed in claim 10 wherein the epitaxially grown thin layer of Ge doped with Sn includes a layer 5 nm thick or less.

14. A device as claimed in claim 10 wherein the epitaxially grown thin layer of Ge doped with Sn includes a layer with a concentration of Sn in a range of 0.5% to 100%.

15. A device as claimed in claim 10 further including an epitaxially grown structure including one of IV material and III-V material on the single crystal layer of Ge.

16. A device as claimed in claim 10 further including an epitaxially grown structure including growing a layer of GaAs on the single crystal layer of Ge.

17. A IV or III-V device fabricated on a germanium template on a silicon substrate comprising:
a crystalline silicon substrate;
a thin layer of Ge epitaxially grown on the silicon substrate, the thin layer including Ge delta doped with Sn at the silicon substrate;
a single crystal layer of Ge epitaxially grown on the thin layer of Ge doped with Sn; and
a structure including one of IV material and III-V material epitaxially grown on the single crystal layer of Ge.

18. A device as claimed in claim 17 wherein the epitaxially grown thin layer of Ge doped with Sn includes a layer 5 nm thick or less.

19. A device as claimed in claim 17 wherein the epitaxially grown thin layer of Ge doped with Sn includes a layer with a concentration of Sn in a range of 0.5% to 100%.
